(19) United States
(12) Patent Application Publication
(10) Pub. No.: US 2007/0075418 A1
(43) Pub. Date: Apr. 5, 2007

(54) EMI SHIELDING DEVICE FOR PCB

(75) Inventor: Chun-Hung Chen, Tu-Cheng,Taipei Hsien (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,270

(22) Filed: Jul. 21, 2006

(30) Foreign Application Priority Data
Sep. 5, 2005 (CN) 200510037136.0

(51) Int. Cl. H01L 23/34; H01L 23/10; H01L 21/00

(52) U.S. Cl. 257/707; 438/125

(57) ABSTRACT

A shielding device is provided for reducing EMI for a PCB. The shielding device includes a plurality of conductive grounded portions arranged on the PCB, an insulating mask, and an auxiliary grounded layer. A plurality of through holes is defined in the insulating mask corresponding to the grounded portions. The auxiliary grounded layer provides a conductive surface. The grounded portions contact the conductive surface via the through holes.

### FIELD OF THE INVENTION

The present invention relates to devices for reducing electromagnetic interference (EMI), and particularly to a device which can efficiently reduce EMI for a printed circuit board (PCB).

### DESCRIPTION OF THE RELATED ART

Today, EMI is a familiar problem in electronics, especially in PCB design. Generally speaking, grounded traces of a PCB all have a little impedance, and each circuit of the PCB is grounded via a grounded trace to minimize noise caused by the impedance and the current of the circuit, which can interfere with other circuits or elements of the PCB. Therefore, when designing a PCB, a grounded layer will be defined in the PCB for aiding in the reduction EMI. However, a layout of the PCB may be very complex, some grounded traces connected between circuits and the grounded layer may need to be long which reduces there effectiveness in preventing EMI.

What is desired, therefore, is to provide a device which can sufficiently reduce EMI for a PCB.

### SUMMARY OF THE INVENTION

In one preferred embodiment, a shielding device is provided for reducing EMI for a PCB. The shielding device includes a plurality of conductive grounded portions arranged on the PCB, an insulating mask, and an auxiliary grounded layer. A plurality of through holes is defined in the insulating mask corresponding to the grounded portions. The auxiliary grounded layer provides a conductive surface. The grounded portions contact the conductive surface via the through holes.

Other advantages and novel features will become more apparent from the following detailed description when taken in conjunction with the accompanying drawings, in which:

### BRIEF DESCRIPTION OF THE DRAWINGS

FIG. 1 is a plane view of grounded portions of a device in accordance with a preferred embodiment of the present invention arranged on a part of a PCB;

FIG. 2 is a plane view of an insulating mask of the device of FIG. 1;

FIG. 3 is a plane view of an auxiliary grounded layer of the device of FIG. 1;

FIG. 4 is an assembled view of FIGS. 1 and 2; and

FIG. 5 is an assembled view of FIGS. 3 and 4.

### DETAILED DESCRIPTION OF THE INVENTION

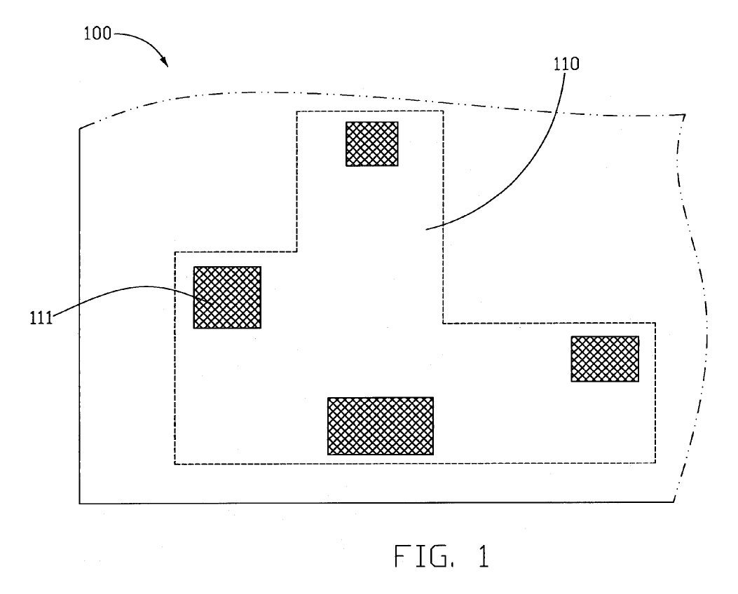

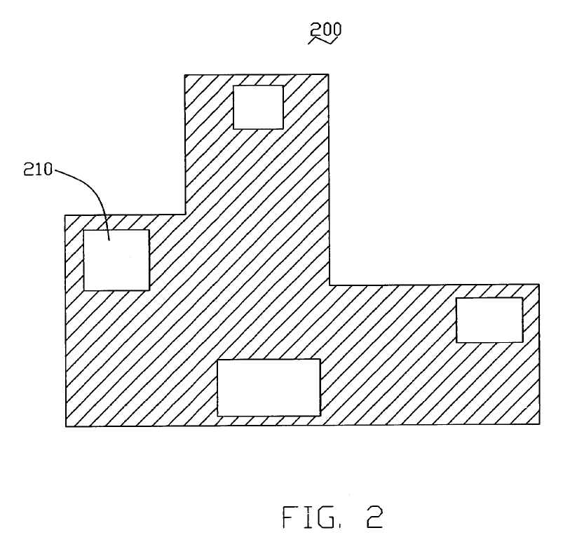

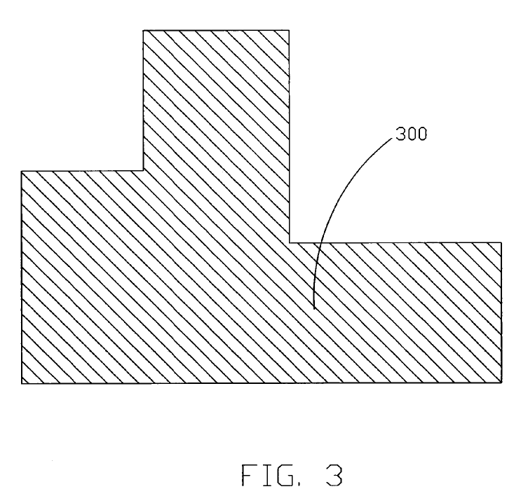

Referring to FIGS. 1-3, a shielding device in accordance with a preferred embodiment of the present invention is provided to reduce EMI for a circuit assembly like a PCB 100 including a motherboard. An area 110 with circuitry is defined on a surface of the PCB 100 where overly long grounded traces would be required in a conventional PCB that can easily cause EMI problem.

The shielding device includes a plurality of electrically conductive grounded portions 111 arranged within the confines of the area 110 to provide shorter routes for grounded traces, the grounded portions 111 are of a size and shape corresponding to available space within the area 110, an insulating mask 200, and an auxiliary grounded layer 300. In this embodiment, the grounded portions 111 are copper foils, the mask 200 is made from any suitable insulating material, and the layer 300 is made of a dielectric coated on one surface thereof with a conductive metal.

A size of the insulating mask 200 generally matches a size of the area 110. A plurality of through holes 210 is defined on the insulating mask 200 corresponding in size, shape, and placement to the grounded portions 111. The auxiliary grounded layer 300 is a same size and shape as the mask 200.

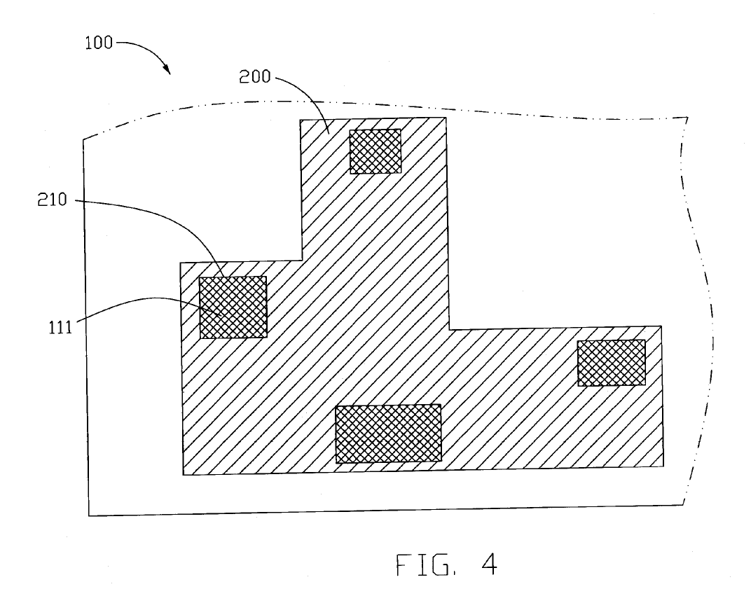

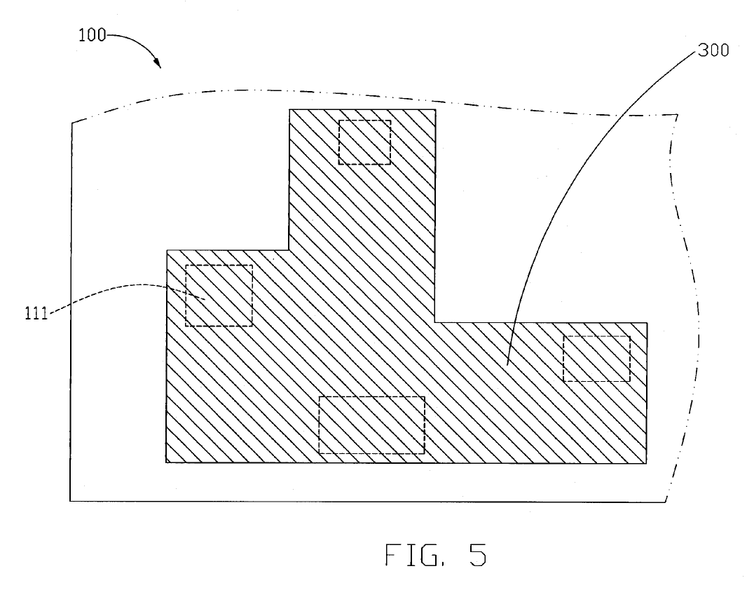

Referring also to FIGS. 4 and 5, in assembly, the insulating mask 200 is attached on the area 110 of the PCB 100, leaving the grounded portions 111 exposed via the corresponding through holes 210. Then the auxiliary grounded layer 300 is aligned with and attached on the insulating mask 200 with the conductive metal coated surface contacting the mask 200 and the grounded portions 111, ensuring electrical contact with the grounded portions 111.

The insulating mask 200 protects traces in the area 110 from contact with the auxiliary grounded layer 300, while at the same time allowing the grounded portions 111 to contact the auxiliary grounded layer 300. With the result that grounded traces have less distance to travel in that area of the PCB 100, and the overall grounded surface area of the PCB 100 is increased thereby reducing EMI of the area 110 giving protection to those traces and/or components in or near the area 110 of the PCB 100.

It is believed that the present embodiments and its advantages will be understood from the foregoing description, and it will be apparent that various changes may be made thereto without departing from the spirit and scope of the invention or sacrificing all of its material advantages, the example hereinbefore described merely being a preferred or exemplary embodiment of the invention.

What is claimed is:

1. A shielding device for reducing electromagnetic interference (EMI) for a printed circuit board (PCB), the shielding device comprising:
a plurality of conductive grounded portions arranged on the PCB;
an insulating mask attached on the PCB and comprising a plurality of through holes corresponding to the grounded portions; and
an auxiliary grounded layer comprising a conductive surface, the grounded portions contacting the conductive surface via the through holes.

2. The shielding device as claimed in claim 1, wherein a size of the insulating mask is the same as a size of the auxiliary grounded layer.

3. The shielding device as claimed in claim 1, wherein a size of each of the through holes is the same as a size of the corresponding grounded portion.

4. The shielding device as claimed in claim 1, wherein the grounded portions are copper foils.

5. A method for reducing electromagnetic interference (EMI) for a printed circuit board (PCB), comprising the steps of:
arranging a plurality of conductive grounded portions on the PCB;
providing an insulating mask comprising a plurality of through holes corresponding to the grounded portions;
providing an auxiliary grounded layer comprising a conductive surface;
attaching the insulating mask on the PCB, the grounded portions being exposed via the corresponding through holes; and
attaching the auxiliary grounded layer on the insulating mask, the grounded portions contacting the conductive surface of the auxiliary grounded layer.

6. The method as claimed in claim 5, wherein a size of the insulating mask is the same as a size of the auxiliary grounded layer.

7. The method as claimed in claim 5, wherein a size of each of the through holes is the same as a size of the corresponding grounded portion.

8. The method as claimed in claim 5, wherein the grounded portions are copper foils.

9. An assembly comprising:
a circuit assembly defining a predetermined area with circuitry therein along a surface of said circuit assembly, said area defining at least one electrically conductive portion therein to be electrically exposable along said surface; and
a shielding device attachable to said circuit assembly along said surface of said circuit assembly, and comprising an auxiliary conductive layer extendable along said surface to electrically cover said area and to be electrically connectable with said at least one electrically conductive portion so as to reduce electromagnetic interference (EMI) along said surface for said area.

10. The assembly as claimed in claim 9, wherein said at least one electrically conductive portion is copper foil to be grounded in said circuit assembly.

11. The assembly as claimed in claim 9, wherein said shielding device further comprises an insulating mask attachable to said area other than said at least one electrically conductive portion to provide electrical insulation between said area and said auxiliary conductive layer of said shielding device.
